(19) United States
(12) Patent Application Publication
(10) Pub. No.: US 2026/0112896 A1
(43) Pub. Date: Apr. 23, 2026

(54) SIMULATION ENGINES FOR HOME ENERGY MANAGEMENT SYSTEMS

(71) Applicant: Enphase Energy, Inc., Petaluma, CA (US)

(72) Inventors: Garvit GOPAL, Prayagraj (IN); Rahul Kumar AGRAWAL, Bangalore (IN); Sandeep PABBATHI, NagarKurnool (IN); Rohit SAINI, Meerut (IN); Alladi AJAY, Guntur (IN); Florian MARCHAT, Antibes (FR); Samuel Marc Frédéric PETITJEAN, Passy (FR); Jinendra Kacharulal GUGALIYA, Mahadevapura (IN); Narasimha Swamy NELAKUDITI, Bangalore (IN)

(21) Appl. No.: 19/360,646

(22) Filed: Oct. 16, 2025

(30) Foreign Application Priority Data
Oct. 18, 2024 (IN) 202411079359

(51) Int. Cl. H02J 3/38; G06F 30/27

(52) U.S. Cl. CPC H02J 3/381; G06F 30/27; H02J 2103/30

(57) ABSTRACT

A simulation engine configured for use with an energy management system is provided and comprises a simulation input generator configured to receive data related to a distributed energy resource (DER) of the energy management system and generate a simulation input, an optimization engine configured to receive the simulation input and generate raw optimization schedule based on the simulation input, a translation layer configured to receive the raw optimization schedule and generate a modified optimization schedule, which is an output compatible with a distributed energy resource (DER) controller of the energy management system, and a system simulator configured to receive the modified optimization schedule to mimic the distributed energy resource (DER) controller, generate a simulation output, and display the simulation output to a user, wherein the simulation output is an end-to-end simulation framework that emulates a behavior of components of the energy management system.

### CROSS-REFERENCE TO RELATED APPLICATIONS

The present application claims the benefit of and priority to Indian Provisional Application Serial No. 202411079359, filed on Oct. 18, 2024, the entire contents of which is incorporated herein by reference.

### BACKGROUND

### Field of the Disclosure

Embodiments of the present disclosure relate generally to home energy management systems (HEMS), and for example, to simulation engines configured for use with HEMS.

### Description of the Related Art

HEMS are configured to optimize how a home-owner's (HO's) home uses energy, helping to keep a HO's bills down and a home comfortable. For homes with solar-plus-storage, a HEMS uses real-time data and automation to determine the best times to store and discharge power, maximizing the benefits of a HO's free, clean electricity. That is, a HEMS ensures that a HO's solar energy goes further. Often a HO can find it difficult for to see an impact of various choices (e.g., savings mode/Self consumption mode, a number of batteries etc.) on end results (e.g., electricity bills).

Thus, the inventors describe herein improved simulation engines configured for use with HEMS.

### SUMMARY

In accordance with aspects of the present disclosure there is provided a simulation engine configured for use with an energy management system. The simulation engine comprises a simulation input generator configured to receive data related to a distributed energy resource (DER) of the energy management system and generate a simulation input, an optimization engine configured to receive the simulation input and generate raw optimization schedule based on the simulation input, a translation layer configured to receive the raw optimization schedule and generate a modified optimization schedule, which is an output compatible with a distributed energy resource (DER) controller of the energy management system, and a system simulator configured to receive the modified optimization schedule to mimic the distributed energy resource (DER) controller, generate a simulation output, and display the simulation output to a user, wherein the simulation output is an end-to-end simulation framework that emulates a behavior of components of the energy management system.

In accordance with aspects of the present disclosure there is provided an energy management system comprising a distributed energy resource (DER), a distributed energy resource (DER) controller operably connected to the distributed energy resource (DER), and a simulation engine comprising a simulation input generator configured to receive data related to the distributed energy resource (DER) and generate a simulation input, an optimization engine configured to receive the simulation input and generate raw optimization schedule based on the simulation input, a translation layer configured to receive the raw optimization schedule and generate a modified optimization schedule, which is an output compatible with a distributed energy resource (DER) controller of the energy management system and a system simulator configured to receive the modified optimization schedule to mimic the distributed energy resource (DER) controller, generate a simulation output, and display the simulation output to a user, wherein the simulation output is an end-to-end simulation framework that emulates a behavior of components of the energy management system.

In accordance with aspects of the present disclosure there is provided a non-transitory computer readable storage medium having instructions stored thereon that when executed by a processor perform a method for running a simulation engine configured for use with an energy management system. The method comprises receiving data related to a distributed energy resource (DER) of the energy management system and generating a simulation input, receiving the simulation input and generate raw optimization schedule based on the simulation input, receiving the raw optimization schedule and generate a modified optimization schedule, which is an output compatible with a distributed energy resource (DER) controller of the energy management system, and receiving the modified optimization schedule to mimic the distributed energy resource (DER) controller, generating a simulation output, and displaying the simulation output to a user, wherein the simulation output is an end-to-end simulation framework that emulates a behavior of components of the energy management system.

These and other features and advantages of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of an energy management system, in accordance with one or more embodiments of the present disclosure;

FIG. 2 is a diagram of high level architecture of a simulation engine that is configured for use with the energy management system of FIG. 1, in accordance with one or more embodiments of the present disclosure;

FIG. 3 is a diagram of detailed architecture of a simulation engine that is configured for use with the energy management system of FIG. 1, in accordance with one or more embodiments of the present disclosure; and

FIG. 4 is a diagram of a sample simulation engine output graph, in accordance with one or more embodiments of the present disclosure.

### DETAILED DESCRIPTION

Embodiments of the present disclosure provide improved simulation engines configured for use with HEMS. For example, a simulation engine can comprise a simulation input generator configured to receive data related to a distributed energy resource (DER) of the energy management system and generate a simulation input. An optimization engine can be configured to receive the simulation input and generate raw optimization schedule based on the simulation input. A translation layer can be configured to receive the raw optimization schedule and generate a modified optimization schedule, which is an output compatible with a distributed energy resource (DER) controller of the energy management system. A system simulator can be configured to receive the modified optimization schedule to mimic the distributed energy resource (DER) controller, generate a simulation output, and display the simulation output to a user, wherein the simulation output is an end-to-end simulation framework that emulates a behavior of components of the energy management system. For example, the end-to-end simulation framework that emulates the behavior of HEMS components allows a HO to understand performance of the HEMS components which can help the HO in selecting different settings and configurations to better meet one or more objectives of the HO.

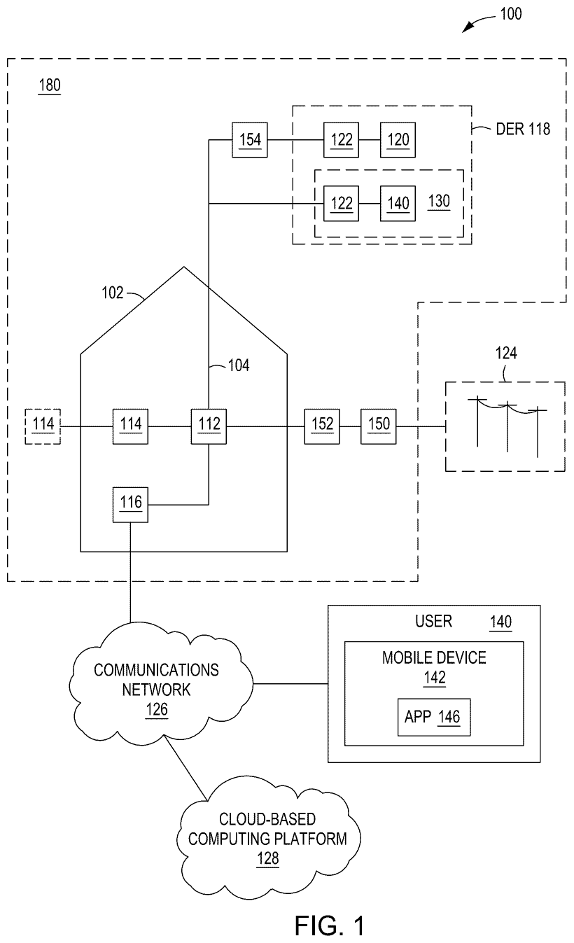

FIG. 1 is a block diagram of an energy management system (e.g., power conversion system, system 100) in accordance with one or more embodiments of the present disclosure. The diagram of FIG. 1 only portrays one variation of the myriad of possible system configurations. The present disclosure can function in a variety of environments and systems.

The system 100 comprises a structure 102 (e.g., a user's structure), such as a residential home, commercial building, or separate mounting structure, having an associated DER 118 (distributed energy resource). The DER 118 can be situated external or internal to the structure 102. For example, the DER 118 as solar power may be located on the roof of the structure 102 or can be part of a solar farm or DER 118 as a battery can be situated inside the residential home The structure 102 comprises one or more loads 114 (and/or energy storage devices), e.g., appliances, electric hot water heaters, thermostats/detectors, boilers, electric vehicle supply equipment (EVSE), water pumps, and the like, which can be located within or outside the structure 102, and a DER controller 116, each coupled to a load center 112 (e.g., a main panel). Although the one or more loads 114, the DER controller 116, and the load center 112 are depicted as being located within the structure 102, one or more of these may be located external to the structure 102.

The load center 112 is coupled to the DER 118 by an AC bus 104 and is further coupled, via a meter 152 and optionally a MID 150 (microgrid interconnect device), to a grid 124 (e.g., a commercial/utility power grid). The structure 102, the one or more loads 114, DER controller 116, DER 118, load center 112, generation meter 154, the meter 152, and the MID 150 are part of a microgrid 180 (e.g., when the system 100 is not connected to the grid 124). It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122. For example, the DER 118 may comprise a plurality of RESs 120 coupled to a plurality of power conditioners 122 in a one-to-one correspondence (or two-to-one or many-to-one or one-to-many or any other configuration). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one (or two-to-one or many-to-one or one-to-many or any other configuration) correspondence, where each pair of power conditioner 122 and a corresponding battery may be referred to as an AC battery.

The power conditioners 122 invert the generated DC power from the plurality of RESs 120 and/or the battery 141 to AC power that is grid-compliant and couple the generated AC power to the grid 124 via the load center 112. The generated AC power may be additionally or alternatively coupled via the load center 112 to the one or more loads (e.g., EV, EVSE) and/or the one or more loads 114. In addition, the power conditioners 122 that are coupled to the batteries 141 convert AC power from the AC bus 104 to DC power for charging the batteries 141. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output. Any AC to DC device which is configured to convert AC generated from renewable sources to DC can be used for charging an EV, e.g., a bi-directional inverter such as a simple charger onboard an EV. A key aspect of the present disclosure is the ability of measuring the energy (AC or DC) supplied to an EV battery.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway or combiner or A Bidirectional EVSE (which includes a gateway and consolidates interconnection equipment into a single enclosure and streamlines PV and storage installations by providing a consistent, pre-wired solution for residential applications) that receives data (e.g., alarms, messages, operating data, performance data, and the like) from the power conditioners 122 and communicates the data and/or other information via the communications network 126 to a cloud-based computing platform 128, which can be configured to execute one or more application software, e.g., a grid connectivity control application, to a mobile app, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application) for performing one or more of the functions described herein. For example, the DER controller 116 can include a memory (e.g., a non-transitory computer readable storage medium) having stored thereon instructions that when executed by a processor perform a method that provides the EVSE with a capability to directly (e.g., using current measurement inputs) or indirectly (e.g., using communication protocols to a remote measurement device) measure a net current being imported from or exported to a grid. Thereafter, the EVSE can use one or more control systems (e.g., an integral power control system (PCS)) to increase and/or decrease the charging and/or discharging rate of the EV to prevent overload of a service transformer, or grid interconnection, or any bus bar / feeder / breaker ratings, as described in greater detail below. Additionally, the DER controller 116 is configured to perform one or more operations associated with the simulation engine, as described below.

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kW) and, in some embodiments, reactive power flow (kVAR). The generation meter 154 may communicate the measured values to the DER controller 116, for example using PLC, other types of wired communications, or wireless communication. Additionally, battery charge/discharge values are received through other networking protocols from the AC battery 130 itself. The generation meter 154 can be internal or external to the DER controller 116.

The meter 152 may be any suitable energy meter that measures the energy consumed/imported by the system 100, such as a net-metering meter, a bi-directional meter that measures energy imported from the grid 124 and as well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kW), reactive power flow (kVAR), grid frequency, and grid voltage. The meter 152 measures power flows independently of MID state, i.e., when MID is closed and DER's are connected to the grid and when MID is open and DER's are isolated from the grid. The meter 152 can be internal or external to the DER controller 116.

The MID 150, which may also be referred to as an island interconnect device (IID), connects/disconnects the system 100 to/from the grid 124. That is, when the system 100 is disconnected from the grid 124, the system 100 becomes a microgrid. The MID 150 comprises a disconnect component (e.g., a contactor or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication), and based on the received information (inputs), the DER controller 116 determines when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124. The MID 150 can be internal or external to the DER controller 116.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly, where the disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, laptop or the like) communicably coupled by wireless/wired means to the communications network 126. The mobile device 142 has a CPU, support circuits, and memory, and has one or more applications (e.g., a grid connectivity control application, the simulation engine application (the application 146)) installed thereon for controlling the connectivity with the grid 124 and/or the real inputs for the simulation engine, as described herein. The may run on commercially available operating systems, such as IOS, ANDROID, WINDOWS and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, the scenarios below, listed in order of priority, will be handled differently. Based on the desired action as entered by the user 140, the corresponding instructions are communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

As noted above, the simulation engines described herein are configured to develop an end-to-end simulation framework that emulates (imitates) the behavior of HEMS components, so that a HO can understand performance of the HEMS components which can help the HO in selecting different settings and configurations to better meet one or more objectives of the HO. For example, in at least some embodiments, the simulation engines can comprise one or more optimization/rule engines and algorithms of optimization and forecasting that can be used by a HO to compare results and suggest the best suite for a site (e.g., a home). In at least some embodiments, the simulation engines can help in optimal system size recommendation for new sites. In at least some embodiments, the simulation engines can help to run various what-if scenarios (e.g., addition of extra battery, PV panel, EVSE to the existing site, etc.). In at least some embodiments, the simulation engines can help in selection of right Tariff regime for a site (e.g., a fixed contract vs dynamic Tariff, etc.).

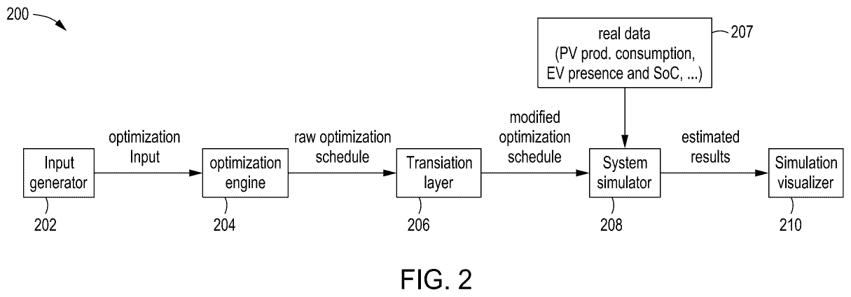

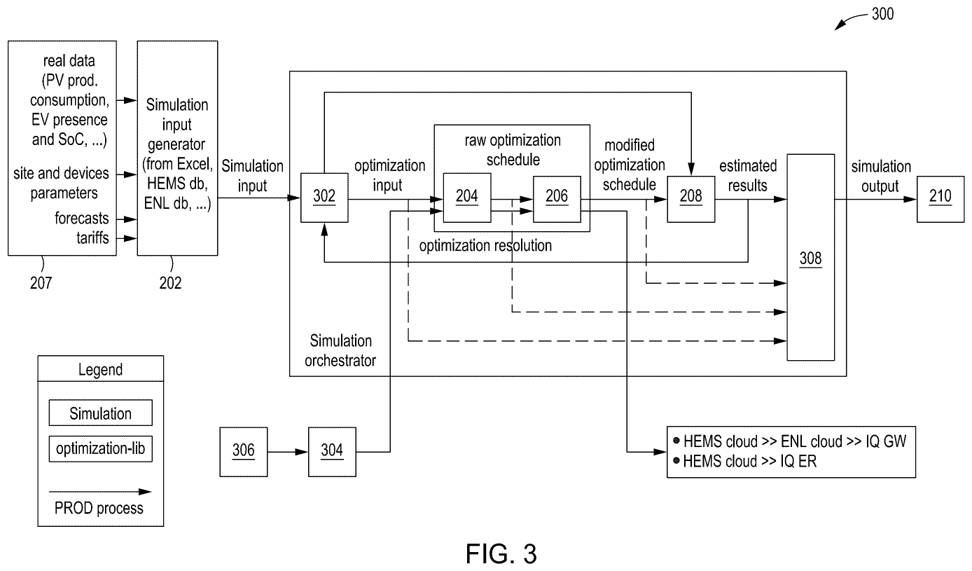

FIG. 2 is a diagram of high level architecture 200 of a simulation engine that is configured for use with the energy management system of FIG. 1, and FIG. 3 is a diagram of detailed architecture 300 of a simulation engine that is configured for use with the energy management system of FIG. 1, in accordance with one or more embodiments of the present disclosure.

For example, an input generator 202 can be configured to create a file of a set of parameters as inputs (e.g., simulation input) required by an optimization engine 204. In at least some embodiments, the set of parameters as inputs (e.g., from a real system 207 such as the system 100) can be provided by Excel, HEMS database, company software (e.g., Enlighten® provided by Enphase® Inc.), etc. and can comprise real system data including PV production/consumption, EV presence and state-of-charge (SoC) of a battery, site and device parameters (e.g., battery capacity, battery charge power, battery charge efficiency, battery operating cost, EVSE capacity, EVSE max charge power, EVSE departure SoC, EVSE plug-in duration, etc.), forecasts, tariffs, etc. In at least some embodiments, a simulation orchestrator 302 (optional) can act as an intermediary module between the input generator 202 and the optimization engine 204. For example, the simulation orchestrator 302 can receive the simulation input from the input generator 202 and can receive estimated results from the system simulator 208, as described in greater detail below. The optimization engine 204 receives an optimization input from the simulation orchestrator 302. The optimization input can also be inputted to a simulation output generator 308, as described in greater detail below. In at least some embodiments, the optimization engine 204 receives an optimization input directly from the input generator 202. The optimization engine 204 can also receive an input from an optimization definition 304, which receives an input from an optimization dispatcher 306. In at least some embodiments, the optimization definition 304 and the optimization dispatcher 306 are not part of the simulation engine, as the optimization definition 304 and the optimization dispatcher 306 can be part of the actual optimization engine deployed on cloud (e.g., a cloud server). The purpose of showing the optimization definition and the optimization dispatcher is to show the common components between simulation engine and the deployed optimization engine.

The result of the optimization is a raw optimization schedule, which may not be directly usable at the gateway or devices level. Accordingly, in at least some embodiments, a translation layer 206 can be configured to make the schedule usable. In such embodiments, the optimization engine 204 can also transmit the information received from the optimization definition 304 to the translation layer 206. The raw optimization schedule can also be inputted to the simulation output generator 308, as described in greater detail below. The output (e.g., a modified optimization schedule) of the translation layer 206 is transmitted to a system simulator 208 that is configured to estimate results of the real system 207. In at least some embodiments, the translation layer 206 can transmit information to a HEMS cloud server, which can transmit information to one or more components (e.g., a gateway (the DER controller 116), IQ ER, etc.) of the system 100. In at least some embodiments, the HEMS cloud server and IQ ER are not part of the simulation engine. The HEMS cloud server and IQ ER can be part of the actual deployed optimization engine, which releases schedules to the HEMS cloud server and the IQ GW and IQ ER (e.g., IQ GW for Battery, IQ ER for EVSE).

The modified optimization schedule can also be inputted to the simulation output generator 308, as described in greater detail below. In at least some embodiments, the estimated results can be transmitted to the simulation output generator 308 which is configured to transmit a simulation output to a simulation-visualizer 210 (e.g., the mobile device 142) that can be configured to represent and simplify the analysis of results.

In operation, the optimization engine 204 functions as a mathematical optimization algorithm that uses forecasts which are generated via one or more machine learning algorithms. In at least some embodiments, ML algorithms such as GBM (gradient boosting algorithm) or ARMA (Auto regressive moving average) type of models can be used. The translation layer 206 translates an optimization output (which can be in the form of charge setpoints (e.g., target power rate at which the battery should be charged to) to an output compatible with the gateway, e.g., the DER controller 116) from the optimization engine 204. The system simulator 208 is configured to mimic the gateway based on real data, charge and discharge of the battery/EVSE in accordance with all the violation checks to give a realistic view of what final bill numbers would look like. For example, the violation checks can be a module (not shown) responsible for checking/ensuring that relative/important physics (e.g., all energy consumers are matching with all energy sources) and power limits on the system (such as max grid import, grid export) are not violated. As noted above, in at least some embodiments, the optimization definition 304 and the optimization dispatcher 306 are not the part of simulation engine, and the optimization definition 304 and the optimization dispatcher 306 are part of (related to) a data fetching mechanism in the deployed version (e.g., on a cloud server) of optimization engine.

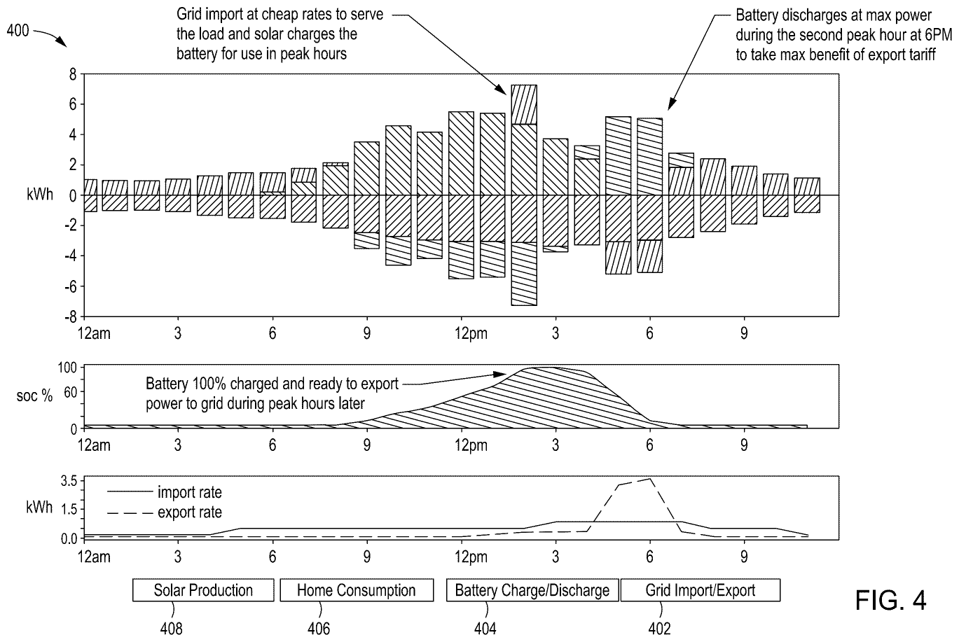

FIG. 4 is a diagram of a sample simulation engine output graph 400, in accordance with one or more embodiments of the present disclosure. For example, a HO can run different what if scenarios by changing one or more inputs. For example, the simulation engine can allow a HO to select various schedulers (e.g., optimization/rule engine, etc.), different objectives (e.g., self-consumption, savings, green charging, etc.), various tariff regimes, simulation of individual components in site, different batteries and microinverter models, different battery configurations (e.g., import only and export only, etc.). Additionally, the simulation engine can output the schedules, battery behaviour, tariffs in an easy-to-understand format, can output a set of KPIs—which are key performance indicators that gives a list of final results, such as, a final bill, self-consumption value, forecast accuracies, total battery charge, total EVSE charge etc., and which give overall view of site performance (e.g., energy independence, bill, savings, grid import/export energy, production to consumption ratio, etc.)—and can output a comparison with rule-based and no-optimization baselines. In at least some embodiments, the simulation engine can output grid import/export information 402 (e.g., a grid import at cheap rates to serve the load and/or solar charges for charging a battery in peak hours). In at least some embodiments, the simulation engine can output battery charge/discharge information 404 (e.g., battery discharges at maximum power during a second peak hour to take maximum benefit of export tariff). In at least some embodiments, the simulation engine can output home consumption information 406. In at least some embodiments, the simulation engine can output solar production information 408.

For example, the simulation engine can transmit (e.g., via the DER controller 116) one or more of the output grid import/export information 402, battery charge/discharge information 404, home consumption information 406, or solar production information 408 to the mobile device 142 (or other suitable display device) so that a HO can perform the one or more what if scenarios by allowing the HO to modify one or more of the output grid import/export information 402, battery charge/discharge information 404, home consumption information 406, or solar production information 408 (e.g., using the live status screen, which can comprise toggle buttons, slides, tabs, or other user touch screen input device). In doing so, the simulation engine allows the DER controller 116 (gateway) to operate quicker and increase overall performance/efficiency of the HEMS components because the simulation engine performs analysis/forecasting based on only those HEMS components that are important to the HO. For example, in at least some embodiments, the DER controller 116 (gateway) uses the simulation engine to perform analysis/forecasting on PV production and SoC of the AC battery 130 but not on, for example, an EVSE/EV when the HO does not need such analysis/forecasting, which allows the DER controller 116 (gateway) to operate more efficiently (e.g., the DER controller 116 (gateway) performs less internal processes).

While the foregoing is directed to embodiments of the present disclosure, other and further embodiments of the disclosure may be devised without departing from the basic scope thereof, and the scope thereof is determined by the claims that follow.

What is claimed IS:

1. A simulation engine configured for use with an energy management system, comprising:
a simulation input generator configured to receive data related to a distributed energy resource (DER) of the energy management system and generate a simulation input;
an optimization engine configured to receive the simulation input and generate raw optimization schedule based on the simulation input;
a translation layer configured to receive the raw optimization schedule and generate a modified optimization schedule, which is an output compatible with a distributed energy resource (DER) controller of the energy management system; and
a system simulator configured to receive the modified optimization schedule to mimic the distributed energy resource (DER) controller, generate a simulation output, and display the simulation output to a user, wherein the simulation output is an end-to-end simulation framework that emulates a behavior of components of the energy management system.

2. The simulation engine of claim 1, wherein the data from the energy management system comprises at least one of photovoltaic (PV) production, consumption, electrical vehicle (EV) presence, or state-of-charge of a battery, site and device parameters, forecasts, tariffs.

3. The simulation engine of claim 1, wherein the optimization engine is further configured to receive an input from an optimization definition, which receives an input from an optimization dispatcher.

4. The simulation engine of claim 3, wherein the optimization definition and the optimization dispatcher are part of the optimization engine.

5. The simulation engine of claim 3, wherein the optimization definition and the optimization dispatcher of are deployed on a cloud server accessible to the user.

6. The simulation engine of claim 1, wherein the translation layer is further configured to transmit information to a home energy management systems (HEMS) cloud server, which can transmit information to at least one component of the energy management system.

7. The simulation engine of claim 1, wherein the simulation output comprises at least one of solar production information, home consumption information, battery charge/discharge information, or grid import/export information.

8. The simulation engine of claim 1, wherein the optimization engine is further configured to function as a mathematical optimization algorithm that uses forecasts which are generated via one or more machine learning algorithms.

9. An energy management system, comprising:
a distributed energy resource (DER);
a distributed energy resource (DER) controller operably connected to the distributed energy resource (DER); and
a simulation engine comprising:
a simulation input generator configured to receive data related to the distributed energy resource (DER) and generate a simulation input;
an optimization engine configured to receive the simulation input and generate raw optimization schedule based on the simulation input;
a translation layer configured to receive the raw optimization schedule and generate a modified optimization schedule, which is an output compatible with a distributed energy resource (DER) controller of the energy management system; and
a system simulator configured to receive the modified optimization schedule to mimic the distributed energy resource (DER) controller, generate a simulation output, and display the simulation output to a user, wherein the simulation output is an end-to-end simulation framework that emulates a behavior of components of the energy management system.

10. The energy management system of claim 9, wherein the data from the energy management system comprises at least one of photovoltaic (PV) production, consumption, electrical vehicle (EV) presence, or state-of-charge of a battery, site and device parameters, forecasts, tariffs.

11. The energy management system of claim 9, wherein the optimization engine is further configured to receive an input from an optimization definition, which receives an input from an optimization dispatcher.

12. The energy management system of claim 11, wherein the optimization definition and the optimization dispatcher are part of the optimization engine.

13. The energy management system of claim 11, wherein the optimization definition and the optimization dispatcher of are deployed on a cloud server accessible to the user.

14. The energy management system of claim 11, wherein the translation layer is further configured to transmit information to a home energy management systems (HEMS) cloud server, which can transmit information to at least one component of the energy management system.

15. The energy management system of claim 9, wherein the simulation output comprises at least one of solar production information, home consumption information, battery charge/discharge information, or grid import/export information.

16. The energy management system of claim 9, wherein the optimization engine is further configured to function as a mathematical optimization algorithm that uses forecasts which are generated via one or more machine learning algorithms.

17. A non-transitory computer readable storage medium having instructions stored thereon that when executed by a processor perform a method for running a simulation engine configured for use with an energy management system, the method comprising:
receiving data related to a distributed energy resource (DER) of the energy management system and generating a simulation input;
receiving the simulation input and generate raw optimization schedule based on the simulation input;
receiving the raw optimization schedule and generate a modified optimization schedule, which is an output compatible with a distributed energy resource (DER) controller of the energy management system; and
receiving the modified optimization schedule to mimic the distributed energy resource (DER) controller, generating a simulation output, and displaying the simulation output to a user, wherein the simulation output is an end-to-end simulation framework that emulates a behavior of components of the energy management system.

18. The non-transitory computer readable storage medium of claim 17, wherein the data from the energy management system comprises at least one of photovoltaic (PV) production, consumption, electrical vehicle (EV) presence, or state-of-charge of a battery, site and device parameters, forecasts, tariffs.

19. The non-transitory computer readable storage medium of claim 17, further comprising receiving an input from an optimization definition, which receives an input from an optimization dispatcher.

20. The non-transitory computer readable storage medium of claim 19, wherein the optimization definition and the optimization dispatcher are part of an optimization engine.
